(19) United States
(12) Patent Application Publication
(10) Pub. No.: US 2012/0056265 A1
(43) Pub. Date: Mar. 8, 2012

(54) SEMINCONDUCTOR DEVICE AND FABRICATIONS THEREOF

(75) Inventors: Wen-Ping Liang, Taoyuan (TW); Kuo-Hui Su, Taoyuan (TW)

(73) Assignee: NANYA TECHNOLOGY CORPORATION, Taoyuan (TW)

(21) Appl. No.: 12/876,933

(22) Filed: Sep. 7, 2010

(51) Int. Cl. H01L 29/78; H01L 21/336

(52) U.S. Cl. 257/347; 438/479; 257/E29.255; 257/E21.409

(57) ABSTRACT

A semiconductor device is disclosed, including a substrate, a fin type semiconductor layer disposed on the substrate, a gate dielectric layer disposed on a top and sidewalls of the fin type semiconductor layer, a metal nitride layer disposed on the gate dielectric layer, and an aluminum doped metal nitride layer disposed on the metal nitride layer. In an embodiment of the invention, the metal nitride layer is a titanium nitride layer and the aluminum doped metal nitride layer is an aluminum doped titanium nitride layer.

### BACKGROUND OF THE INVENTION

1. Field of the Invention

This invention generally relates to a semiconductor device and fabrications thereof and more particularly to a fin field effect transistor and fabrication thereof.

2. Description of the Related Art

As the semiconductor industry has progressed into nanometer technology process nodes in pursuit of higher device density, higher performance, and lower costs, challenges from both fabrication and design issues have resulted in the development of three dimensional designs, such as a fin field effect transistor (FinFET). A typical FinFET is fabricated with a thin ‘fin’ extending from a substrate, for example, etched into a silicon layer of the substrate. The channel of the FET is formed in this vertical fin. A gate is provided over (e.g., wrapping) the fin. It is beneficial to have a gate on both sides of the channel allowing gate control of the channel from both sides. Further advantages of FinFETs include reduction of short channel effect and higher current flows.

There are issues associated with fabrication of FinFETs. FIGS. 1A-1C show fabrication of a traditional fin field effect transistor. Referring to FIG. 1A, a substrate 102, such as silicon, is provided. A fin 104, such as a poly silicon fin, is formed on the substrate 102. A gate dielectric layer 106 is formed on the top and the sidewalls of the fin 104. Next, a titanium nitride layer 108 is formed on the gate dielectric layer 106, acting as a gate electrode. Referring to FIG. 1B, a silicon nitride layer 110 and a tetraethoxysilane (TEOS) layer 112 are sequentially formed on the titanium nitride layer 108 to prevent oxidation of the titanium nitride layer 108 during subsequent process steps. Thereafter, referring to FIG. 1C, a spin-on dielectric (SOD) layer 114 is blanketly deposited on the TEOS layer 112, followed by performing annealing steps at about 800° C. for dense of the SOD layer 114. One issue associated with fabrication of FinFETs, is that the distance between fins is shrinking. Thus, if thickness of the silicon oxide layer and the TEOS layer 112 are increased, voids are generated in the SOD layer 114 (so-called SOD void issue). Therefore, a new fin field effect transistor and fabrication thereof are required to address this issue.

### BRIEF SUMMARY OF INVENTION

The invention provides a semiconductor device, comprising a substrate, a fin type semiconductor layer disposed on the substrate, a gate dielectric layer disposed on a top and sidewalls of the fin type semiconductor layer, a metal nitride layer disposed on the gate dielectric layer, and an aluminum doped metal nitride layer disposed on the metal nitride layer. In an embodiment of the invention, the metal nitride layer is a titanium nitride layer and the aluminum doped metal nitride layer is an aluminum doped titanium nitride layer.

The invention provides a fin field effect transistor device, comprising a fin type semiconductor layer, a gate structure wrapping around the fin type semiconductor layer, wherein the gate structure comprises a gate dielectric layer and a titanium nitride layer, and an oxidation barrier layer protecting the titanium nitride layer from oxidation, wherein the oxidation barrier layer comprises aluminum doped titanium nitride layer.

The invention provides a method for forming a semiconductor device, comprising providing a substrate, forming a fin type semiconductor layer on the substrate, forming a gate dielectric layer on a top and sidewalls of the fin type semiconductor layer, forming a metal nitride layer on the gate dielectric layer; and forming an aluminum doped metal nitride layer on the metal nitride layer.

### BRIEF DESCRIPTION OF DRAWINGS

The invention can be more fully understood by reading the subsequent detailed description and examples with references made to the accompanying drawings, wherein,

FIGS. 1A-1C show fabrication of a traditional fin field effect transistor.

FIG. 2A shows a plan view of a fin field effect transistor (FinFET) of an embodiment of the invention.

FIG. 2B-2D shows cross sections of various stages during fabrication of a fin field effect transistor (FinFET) of an embodiment of the invention.

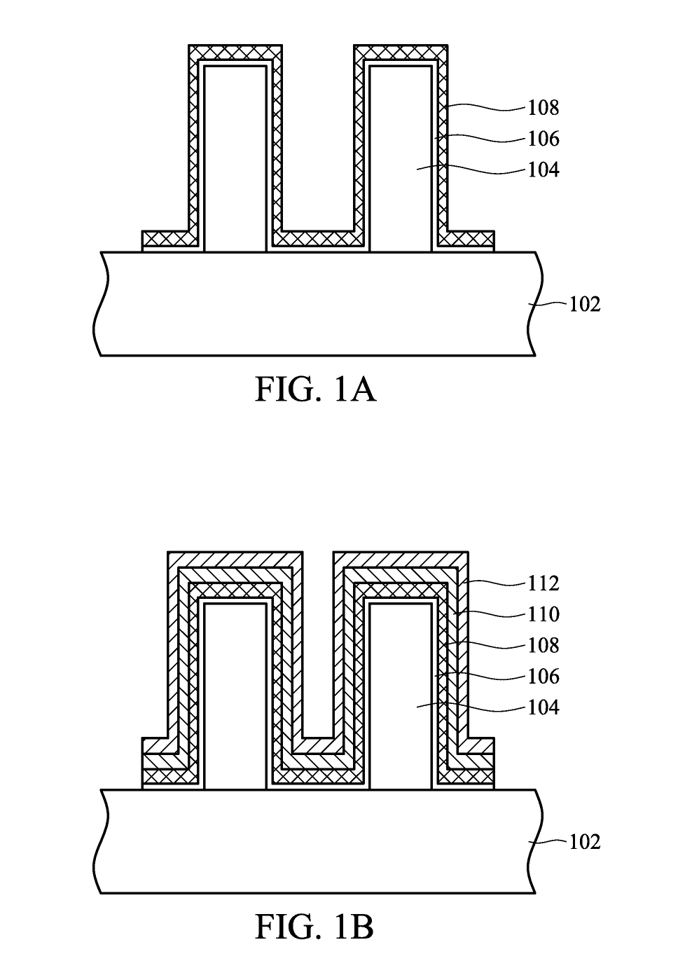

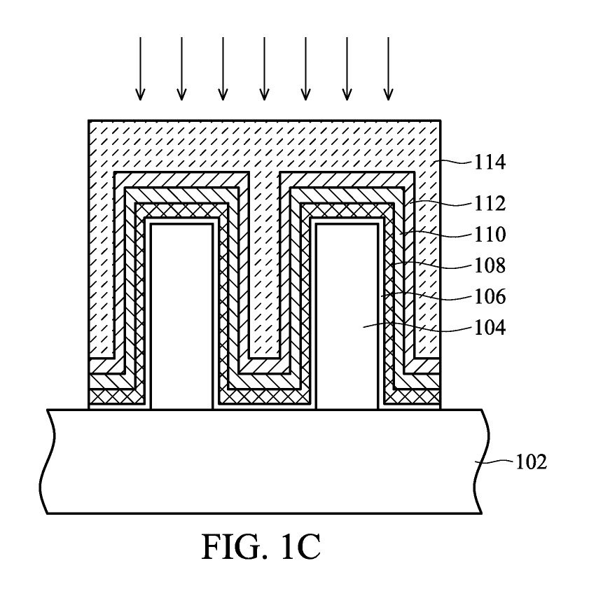

### DETAILED DESCRIPTION OF INVENTION

It is understood that specific embodiments are provided as examples to teach the broader inventive concept, and one of ordinary skill in the art can easily apply the teaching of the present disclosure to other methods or apparatus. In addition, it is understood that the methods and device discussed in the present disclosure include some conventional structures and/or processes. Since these structures and processes are well known in the art, they will only be discussed in a general level of detail. Furthermore, reference numbers are repeated throughout the drawings for sake of convenience and example, and such repetition does not indicate any required combination of features or steps throughout the drawings. Moreover, the formation of a first feature over and on a second feature in the description that follows may include embodiments in which the first and second features are formed in direct contact, and may also include embodiments in which additional features may be formed interposing the first and second features, such that the first and second features may not be in direct contact. A FinFET device as the term is employed in the current disclosure provides any fin-based, multi-gate transistor.

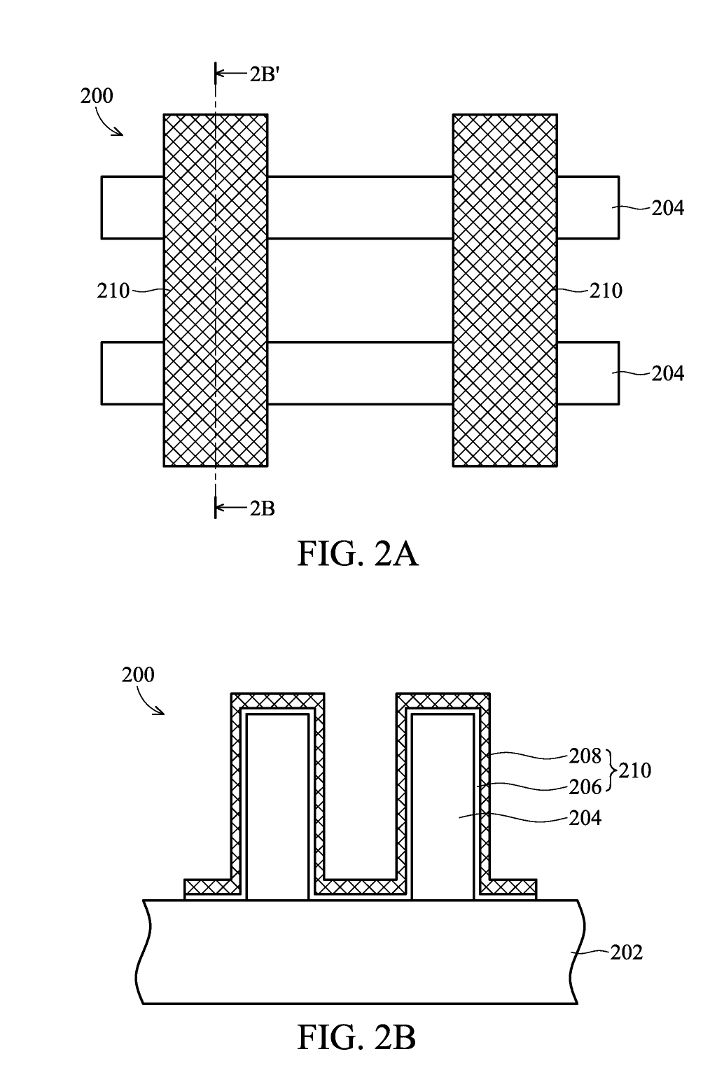

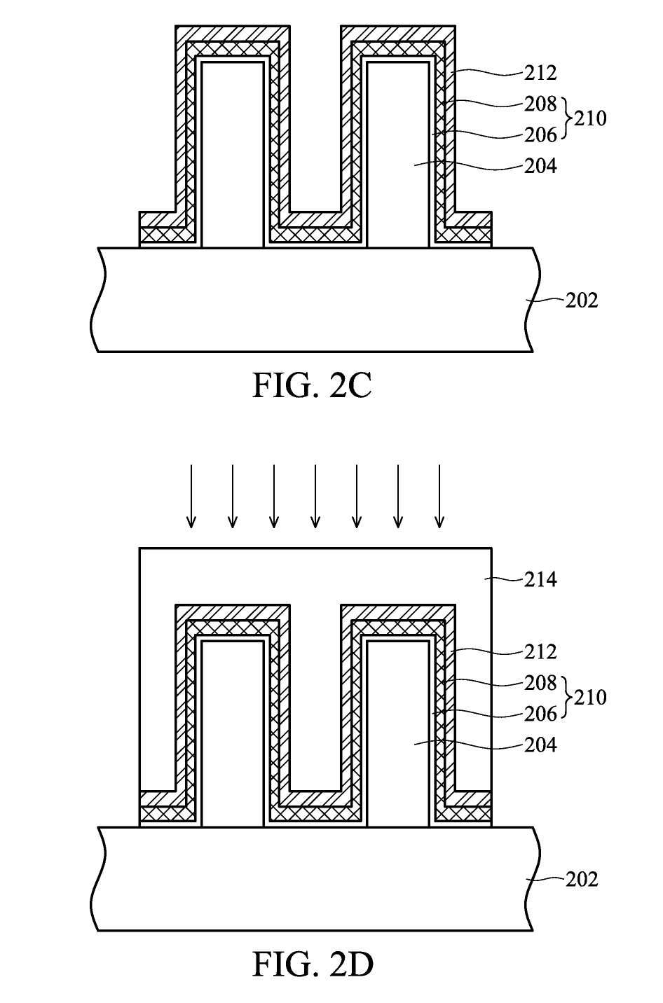

FIG. 2A shows a plan view of a fin field effect transistor (FinFET) of an embodiment of the invention. FIG. 2B-2D shows cross sections of various stages during fabrication of a fin field effect transistor (FinFET) of an embodiment of the invention. It is noted that FIG. 2B is a cross-sectional view along one of the fins as is shown by the plan view in FIG. 2A. Referring to FIG. 2A and FIG. 2B, the semiconductor device 200 includes a plurality of fins 204 (also called fin type semiconductor layer) that extend from the substrate 202. Although only two fins 204 are shown, it is understood that the number of fins 204 may vary depending on particular applications. The fins 204 include silicon or polysilicon fins. The fins 204 may be fabricated by using suitable processes such as photolithography and etching processes. For example, the photolithography process may include forming a photoresist layer (resist) overlying the substrate 202 (e.g., on a silicon layer or a poly silicon layer), exposing the photoresist layer to pattern, performing post-exposure baking processes, and developing the photoresist layer to form a masking element. The masking element may then be used to etch the fins 204 from the substrate 202. The fins 204 may be etched using reactive ion etch (RIE) processes and/or other suitable processes.

In other embodiments, the substrate 202 includes a silicon-on-insulator (SOT) substrate. The SOI substrate may be fabricated by implantation of oxygen (SIMOX), wafer bonding, and/or other suitable methods. The layer of silicon may be a silicon layer of an SOI substrate (e.g., overlying an insulator layer). The fins 204 may be formed, for example, by etching a layer of silicon on the substrate or a polysilicon layer on the substrate.

In an embodiment, the fins 204 may be formed by a double-patterning lithography (DPL) process. The DPL process is a method of constructing a pattern on a substrate by dividing the pattern into two interleaved patterns. The DPL process allows for fabrication of enhanced feature (e.g., fin) density. Various DPL processes have been disclosed including, double exposure (e.g., using two mask sets), adjacent feature spacer formation and feature removal processes to provide a pattern of spacers, and resist freezing, and/or other suitable processes.

Referring to FIG. 2C, the semiconductor device 200 includes one or more gate structures 210 that are formed over a portion of each of the fins 204 of the substrate 202. It is noted that the gate structures 210 wrap around the fins 204 allowing gate control of the channel from both sides of the fin 204. The gate structure 210 includes a gate dielectric layer 206 and a metal nitride layer 208 formed along the top and sidewalls of the fin 204. The gate dielectric layer 206 may include materials such as silicon oxide, silicon nitride, and high-k dielectric materials, or other suitable materials. The high-k dielectric layer may include a binary or ternary high-k film such as HfOₓ. Alternatively, the high-k dielectric layer may optionally include other high-k dielectrics such as LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides, or other suitable materials. The gate dielectric layer 206 is formed by a suitable process such as an atomic layer deposition (ALD), chemical vapor deposition (CVD), thermal oxidation, or UV-ozone oxidation process, or combinations thereof. The metal nitride layer preferably is a titanium nitride layer, which can be formed by a suitable process such as atomic layer deposition (ALD) or chemical vapor deposition (CVD) processes. In an embodiment of the invention, thickness of the metal nitride layer 208 is about 5 Å˜10 Å.

Referring to FIG. 2C, an aluminum doped metal nitride layer 208 is formed on the metal nitride layer 208. The aluminum doped metal nitride layer 208 can be an aluminum doped titanium nitride layer. The aluminum doped metal nitride layer 208 is formed by a suitable process such as an atomic layer deposition (ALD) or chemical vapor deposition (CVD) process. In an embodiment of the invention, the aluminum doped metal nitride layer 208 is in-situ formed after forming the metal nitride layer 208. That is, after forming the metal nitride layer 208 in a chamber, the chamber is inlet with aluminum containing gas in accordance with the gas for forming the metal nitride layer 208 to form the aluminum doped metal nitride layer 208. Aluminum concentration of the aluminum doped metal nitride layer 208 preferably is more than 5%, because XRD analysis shows that TiN doped with aluminum more than 5% can provide a better oxidation barrier performance to prevent TiN from oxidation during subsequent process steps. In an embodiment of the invention, thickness of the aluminum doped metal nitride is about 40 Å˜60 Å.

Thereafter, referring to FIG. 2D, a dielectric layer 214 is blanketly formed on the aluminum doped metal nitride layer 208 and filled into the space between fins 204. The dielectric layer 214 can be an oxide containing layer and can be formed by spin-on dielectric (SOD) process, followed by performing annealing steps at about 800° C. for dense of the dielectric layer 214.

The invention replaces the silicon nitride and TEOS barrier layer with an aluminum doped metal nitride layer 208 and has the following advantages. First, the aluminum doped metal nitride layer 208 has good barrier performance and is thinner than the silicon nitride and TEOS barrier layer, such that the space between fins can be increased for SOD filling to eliminate SOD void issues. Second, the aluminum doped metal nitride layer 208 can be in-situ formed at the same chamber for forming the metal nitride layer 208. Therefore, the invention can save process time and/or cost. Third, the invention can fine tune the aluminum concentrations of the aluminum doped metal nitride layer 208 for better process flexibility.

While the invention has been described by way of example and in terms of the preferred embodiments, it is to be understood that the invention is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate;
a fin type semiconductor layer disposed on the substrate;
a gate dielectric layer disposed on a top and sidewalls of the fin type semiconductor layer;
a metal nitride layer disposed on the gate dielectric layer; and
an aluminum doped metal nitride layer disposed on the metal nitride layer for preventing oxidation of the metal nitride layer.

2. The semiconductor device as claimed in claim 1, wherein the metal nitride layer is a titanium nitride layer.

3. The semiconductor device as claimed in claim 2, wherein the aluminum doped metal nitride layer is an aluminum doped titanium nitride layer.

4. The semiconductor device as claimed in claim 3, wherein aluminum concentration of the aluminum doped titanium nitride layer is more than 5%.

5. The semiconductor device as claimed in claim 1, further comprising a dielectric layer on the aluminum doped metal nitride layer.

6. The semiconductor device as claimed in claim 5, wherein the dielectric layer is an oxide layer.

7. The semiconductor device as claimed in claim 1, wherein the fin type semiconductor layer comprises silicon or poly silicon material.

8. The semiconductor device as claimed in claim 1, wherein thickness of the metal nitride layer is about 5 Å˜10 Å.

9. The semiconductor device as claimed in claim 1, wherein thickness of the aluminum doped metal nitride layer is about 40 Å˜60 Å.

10. The semiconductor device as claimed in claim 1, wherein the aluminum doped metal nitride layer acts as an oxidation barrier layer of the metal nitride layer.

11. A fin field effect transistor device, comprising:
a fin type semiconductor layer;
a gate structure wrapping around the fin type semiconductor layer, wherein the gate structure comprises a gate dielectric layer and a titanium nitride layer; and
an oxidation barrier layer protecting the titanium nitride layer from oxidation, wherein the oxidation barrier layer comprises an aluminum doped titanium nitride layer.

12. The fin field effect transistor device as claimed in claim 11, wherein aluminum concentration of the aluminum doped titanium nitride layer is more than 5%.

13. The fin field effect transistor device as claimed in claim 11, wherein thickness of the titanium nitride layer is about 5 Å˜10 Å.

14. The fin field effect transistor device as claimed in claim 11, wherein thickness of the oxidation barrier layer is about 40 Å˜60 Å.

15. A method for forming a semiconductor device, comprising:
providing a substrate;
forming a fin type semiconductor layer on the substrate;
forming a gate dielectric layer on a top and sidewalls of the fin type semiconductor layer;
forming a metal nitride layer on the gate dielectric layer; and
forming an aluminum doped metal nitride layer on the metal nitride layer.

16. The method for forming a semiconductor device as claimed in claim 15, wherein the metal nitride layer is a titanium nitride layer.

17. The method for forming a semiconductor device as claimed in claim 15, wherein the aluminum doped metal nitride layer is an aluminum doped titanium nitride layer.

18. The method for forming a semiconductor device as claimed in claim 15, wherein the aluminum doped metal nitride layer is in-situ formed after forming the metal nitride layer.

19. The method for forming a semiconductor device as claimed in claim 15, wherein the metal nitride layer and the aluminum doped metal nitride layer are formed by atomic layer deposition (ALD) or chemical vapor deposition (CVD).

20. The method for forming a semiconductor device as claimed in claim 17, wherein aluminum concentration of the aluminum doped titanium nitride layer is more than 5%.
